(19) United States
(12) Patent Application Publication
(10) Pub. No.: US 2024/0151999 A1
(43) Pub. Date: May 9, 2024

(54) CHOLESTEROL LIQUID CRYSTAL DISPLAY DEVICE INTEGRATED WITH SOLAR MODULES

(71) Applicant: IRIS OPTRONICS CO., LTD., Tainan City (TW)

(72) Inventors: NIEN-CHIEH WANG, Tainan City (TW); YAO-JEN HSIEH, Tainan City (TW); CHI-CHANG LIAO, Tainan City (TW)

(21) Appl. No.: 18/503,167

(22) Filed: Nov. 6, 2023

(30) Foreign Application Priority Data
Nov. 8, 2022 (TW) 111142534

(51) Int. Cl. G02F 1/133; G02F 1/1343; G02F 1/1347; G02F 1/137

(52) U.S. Cl. CPC G02F 1/13324; G02F 1/134309; G02F 1/13439; G02F 1/1347; G02F 1/137; G02F 2202/28

(57) ABSTRACT

A cholesterol liquid crystal display device integrated with solar modules includes a first transparent substrate, a second transparent substrate, a first cholesterol liquid crystal module and a solar module. The first cholesterol liquid crystal module is arranged between the first transparent substrate and the second transparent substrate. The solar module is arranged between the first transparent substrate and the first cholesterol liquid crystal module. Therefore, the cholesterol liquid crystal display device of the present invention does not need a backlight module. By combining the light transmission characteristics of the cholesterol liquid crystal display device with the coating process characteristics of the solar module, the cholesterol liquid crystal display device with energy conservation and environmental protection is formed.

### BACKGROUND OF THE INVENTION

### 1. Field of the Invention

The present invention relates to a display device, and in particular to a cholesteric liquid crystal display device integrated with solar modules.

### 2. Description of Related Art

Cholesteric liquid crystal display is one type of liquid crystal displays. Cholesteric liquid crystals exhibit bi-stable characteristics, meaning they have two stable states without the need for external voltages. This differs from the TFT (Thin-Film Transistor) liquid crystal displays commonly used today.

The arrangement of cholesteric liquid crystal molecules has two stable states: the Focal Conic State and the Planar State, giving it bistable characteristics. This means that cholesteric liquid crystal molecules do not require additional energy from external sources to maintain their original molecular arrangement. When a voltage is applied, the arrangement of cholesteric liquid crystal molecules can switch between these two stable states: the focal conic state and the planar state. As mentioned earlier, when cholesteric liquid crystal molecules are in the planar state, they reflect light of a specific wavelength; conversely, when they are in the focal conic state, light can penetrate through them. Therefore, the voltage applied to cholesteric liquid crystal molecules can be utilized to control whether they allow light to penetrate or reflect light of a specific wavelength.

Existing TFT (Thin-Film Transistor) liquid crystal displays often suffer from a significant power consumption issue. They are unable to display information while simultaneously collecting and converting light energy into electrical energy for practical use. As a result, they fall short of fulfilling the initial goal of environmental conservation and energy efficiency.

Therefore, the primary objective of the present invention is to offer a cholesteric liquid crystal display device that incorporates solar modules, aiming to address the aforementioned issues.

### SUMMARY OF THE INVENTION

The objective of the present invention is to introduce a cholesteric liquid crystal display device that incorporates solar modules without the need for a backlight module. This integration is achieved by harnessing the light-transmitting properties of the cholesteric liquid crystal display device and leveraging the coating process characteristics of the solar modules. Thus, a cholesteric liquid crystal display device of the present invention is capable of collecting and converting light energy into electrical energy for practical use while simultaneously displaying information. This approach aligns with the goals of environmental conservation and energy efficiency.

To realize at least one of the aforementioned advantages or other benefits, one embodiment of the present invention provides a cholesteric liquid crystal display device integrated with solar modules. This device comprises a first transparent substrate, a second transparent substrate, a first cholesteric liquid crystal module, and a solar module.

The first cholesteric liquid crystal module is disposed between the first transparent substrate and the second transparent substrate, while the solar module is disposed between the first transparent substrate and the first cholesteric liquid crystal module.

In certain embodiments, the solar module comprises a sequential stacking of the following layers on the first transparent substrate: a first transparent electrode layer, a hole transport layer, a perovskite light absorption layer, an electron transport layer, a second transparent electrode layer, and an insulating layer.

In some embodiments, the solar module can be a perovskite solar photovoltaic device.

In certain embodiments, the cholesteric liquid crystal display device further comprises a third transparent substrate, a second cholesteric liquid crystal module, a fourth transparent substrate, a fifth transparent substrate, a third cholesteric liquid crystal module, and a sixth transparent substrate, all of which are sequentially stacked on the second transparent substrate.

In certain embodiments, the cholesteric liquid crystal display device further comprises a first optical adhesive layer and a second optical adhesive layer. The first optical adhesive layer is positioned between the second transparent substrate and the third transparent substrate, while the second optical adhesive layer is provided between the fourth transparent substrate and the fifth transparent substrate.

In certain embodiments, the first cholesteric liquid crystal module is used to generate a first color light, the second cholesteric liquid crystal module is utilized to produce a second color light, and the third cholesteric liquid crystal module is harnessed to generate a third color light. These three colors, first, second, and third color light, are distinct from each other, and when the first color light and second color light are mixed, it results in a fourth color light. The first optical adhesive layer is designed for transmitting the first color light, while the second optical adhesive layer is designed for transmitting the fourth color light.

In some embodiments, each of the first cholesteric liquid crystal module, the second cholesteric liquid crystal module, and the third cholesteric liquid crystal module comprises a lower electrode layer, a cholesteric liquid crystal layer, and an upper electrode layer stacked in sequence.

In some embodiments, each of the first cholesteric liquid crystal module, the second cholesteric liquid crystal module and the third cholesteric liquid crystal module further comprises a reinforcement layer, and the reinforcement layer is configured between the lower electrode layer and the upper electrode layer.

In some embodiments, the driving scheme of the cholesteric liquid crystal display device is a passive matrix mode or an active matrix mode.

In some embodiments, the cholesteric liquid crystal display device further comprises a black absorption layer disposed on a side of the first transparent substrate away from the solar module.

Therefore, through the utilization of the cholesteric liquid crystal display device integrated with the solar modules of the present invention, by combining the light-transmitting properties of the cholesteric liquid crystal display device with the coating process characteristics of the solar module, the cholesteric liquid crystal display device is integrated. The cholesteric liquid crystal display device of the present invention can not only display information but also collect light energy and convert it into electrical energy for practical use, thereby achieving the goals of environmental conservation and energy efficiency.

The aforementioned illustrations are exemplary for the purpose of further explaining the scope of the present invention. Other objectives and advantages related to the present invention will be illustrated in the subsequent descriptions and appended drawings.

### BRIEF DESCRIPTION OF THE DRAWINGS

The foregoing features of the present invention may be combined with the following drawings in various combinations without exclusivity, unless expressly indicated otherwise. Apparently, descriptions of drawings in the following may be some of embodiments of the present invention, those of ordinary skill in the art may derive other drawings based on the following drawings without unduly experiments.

FIG. 1 is a schematic of a cholesteric liquid crystal display device integrated with solar modules according to an embodiment of the present invention; and

FIG. 2 is a schematic of a cholesteric liquid crystal display device integrated with solar modules according to another embodiment of the present invention.

### DETAILED DESCRIPTION OF THE PREFERRED EMBODIMENTS

The aforementioned constructions and associated functions and following detailed descriptions are exemplary for the purpose of further explaining the scope of the present invention. Other objectives and advantages related to the present invention will be illustrated in the subsequent descriptions and appended drawings. Furthermore, the present invention may be embodied in various modifications, and descriptions and illustrations are not-limiting.

It should be understood that the term used herein in embodiments to describe direction in terms of “central”, “lateral”, “up”, “down”, “right”, “left”, “upright”, “horizontal”, “top”, “bottom”, “inside”, and “outside” are used to illustrate the present invention and for clarity. It does not hint or imply that device or part mentioned should be assembled or operated in specific direction or setting. Thus, the terms used herein to describe direction are not limiting. In addition, terms “first”, and “second” is for descriptive purpose, and is not construed to or implies amount as described in technical feature of the present invention. Technical features with limitation terms “first” or “second” would illustrate or imply that one or more technical features can be included. As to detailed description of the present invention, the term “more” indicates two or more unless expressly indicated otherwise.

As to detailed descriptions of the present invention, it will be further explained that the term “assemble”, “connected to”, “connected” should be construed in broadest way, unless the context clearly indicates otherwise. For example, the term “connected” indicates that two parts may be “fixed connected” or “detachably connected” or “integrally connected”. Similarly, the term “connected” also indicates that two parts may be “mechanically connected” or “electrically connected”, and “directly connected”, “connected by intermediate part” or “internally connected by two parts”. Alterations or modifications of the terms mentioned above will be no doubt understood and obvious to those of ordinary skill in the art.

The terminology used herein is for the purpose of describing embodiments only and is not intended to limit the full scope of the present invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, or components and the like, but do not preclude the presence or addition of one or more other features, integers, steps, operations, elements, components, and/or groups thereof.

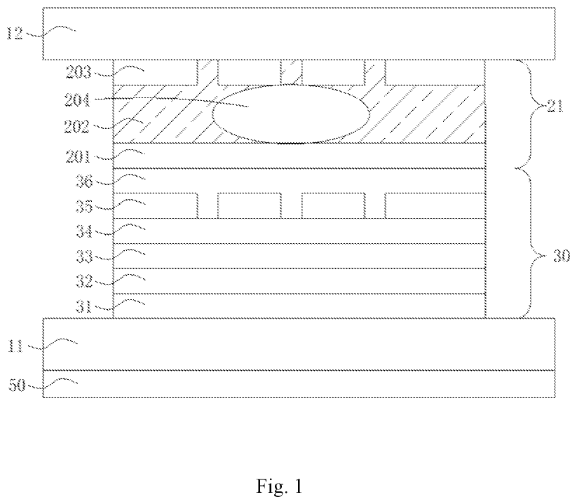

Please refer to FIG. 1, which is a schematic of a cholesteric liquid crystal display device 1 integrated with solar modules 30, as per an embodiment of the present invention. In order to achieve at least one of the aforementioned advantages or other benefits, the embodiment of the present invention provides a cholesteric liquid crystal display device 1 integrated with the solar modules 30. This integrated device may comprises a first transparent substrate 11, a second transparent substrate 12, a first cholesteric liquid crystal module 21, and a solar module 30.

The first cholesteric liquid crystal module 21 is disposed between the first transparent substrate 11 and the second transparent substrate 12, and the solar module 30 is implemented between the first transparent substrate 11 and the first cholesteric liquid crystal module 21. To clarify, when examining the cholesteric liquid crystal display device 1 from bottom to top in FIG. 1, the arrangement is as follows: the first transparent substrate 11, the solar module 30, the first cholesteric liquid crystal module 21, and the second transparent substrate 12 in that order. Through the combination of the light-transmitting characteristics of the cholesteric liquid crystal display device 1 and the coating process characteristics of the solar module 30, the solar module 30 can be positioned between the first transparent substrate 11 and the first cholesteric liquid crystal module 21 (i.e., on the upper side of the first transparent substrate 11 in FIG. 1). In contrast, conventional solar devices are typically limited to installation on the lower side of the first transparent substrate 11 and are unable to simultaneously display information, collect light energy, and convert it into electrical energy, thus limiting their ability to achieve environmental conservation and energy savings.

In certain embodiments, the solar module 30 comprises the following sequential layers stacked on the first transparent substrate 11: a first transparent electrode layer 31, a hole transport layer 32, a perovskite light-absorbing layer 33, an electron transport layer 34, a second transparent electrode layer 35, and an insulating layer 36. Specifically, the perovskite light-absorbing layer 33 is responsible for absorbing photons and creating electron-hole pairs. The generated holes are transmitted to the first transparent electrode layer 31 through the hole transport layer 32, while the generated electrons are transmitted to the second transparent electrode layer 35 through the electron transport layer 34. Preferably, the solar module 30 employs a perovskite solar photovoltaic device to capture light energy and generate electrical energy. It may be coupled to an external electrical energy collection circuit to fulfill the objectives of energy conservation and carbon reduction.

The first cholesteric liquid crystal module 21 may consist of the following sequential layers, arranged from bottom to top: a lower electrode layer 201, a cholesteric liquid crystal layer 202, and an upper electrode layer 203. The lower electrode layer 201 and upper electrode layer 203 are utilized to apply voltages to the cholesteric liquid crystal layer 202, thereby adjusting the molecular arrangement of the cholesteric liquid crystal layer 202 to generate light. Additionally, the first cholesteric liquid crystal module 21 may comprise a reinforcement layer 204 positioned between the lower electrode layer 201 and the upper electrode layer 203, enhancing the overall structural stability of the module.

In certain embodiments, the cholesteric liquid crystal display device 1 may also comprise a black absorption layer 50. This black absorption layer 50 is implemented on the side of the first transparent substrate 11 opposite to the solar module 30, allowing the cholesteric liquid crystal display device 1 to display a black appearance.

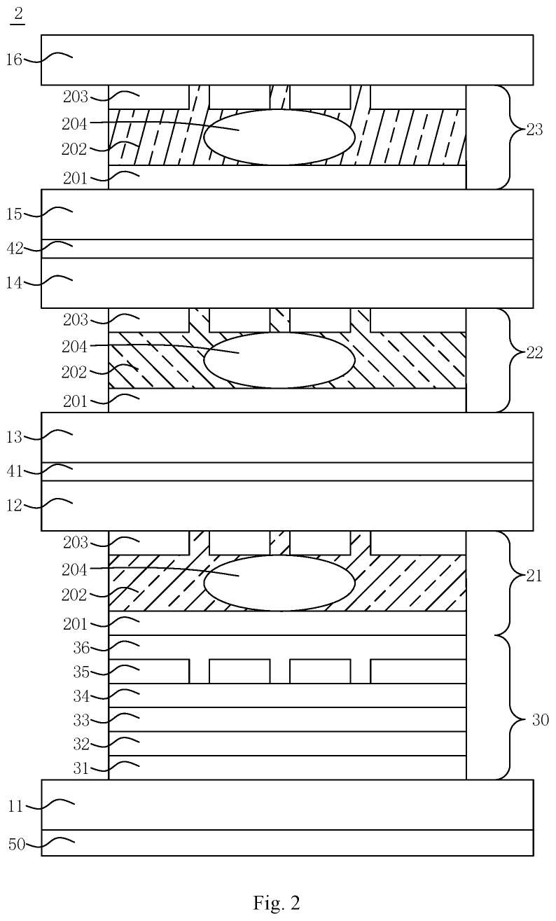

Please refer to FIG. 2, which illustrates a schematic of a cholesteric liquid crystal display device 2 integrated with solar modules 30, according to another embodiment of the present invention. To achieve at least one of the aforementioned advantages or other benefits, this embodiment of the present invention introduces another cholesteric liquid crystal display device 2 integrated with a solar module 30. In comparison to the cholesteric liquid crystal display device 1 depicted in FIG. 1, the cholesteric liquid crystal display device 2 in this embodiment also features a configuration consisting of a third transparent substrate 13, a second cholesteric liquid crystal module 22, a fourth transparent substrate 14, a fifth transparent substrate 15, a third cholesteric liquid crystal module 23, and a sixth transparent substrate 16. These components are sequentially stacked on the second transparent substrate 12.

In some embodiments, the cholesteric liquid crystal display device 2 may also comprise a first optical adhesive layer 41 and a second optical adhesive layer 42. The first optical adhesive layer 41 is disposed between the second transparent substrate 12 and the third transparent substrate 13. The second optical adhesive layer 42 is disposed between the fourth transparent substrate 14 and the fifth transparent substrate 15.

The first cholesteric liquid crystal module 21 generates the first color light, the second cholesteric liquid crystal module 22 produces the second color light, and the third cholesteric liquid crystal module 23 is responsible for the third color light. The first, second, and third color lights are distinct. For example, when external light interacts with the cholesteric liquid crystal display device 2, the first cholesteric liquid crystal module 21 reflects the first color light present in the incident light, resulting in the generation of the first color light. The same principle applies to the second and third color lights, enabling the cholesteric liquid crystal display device 2 to achieve full-color representation. Additionally, when the first color light and the second color light are mixed, the resulting color light is defined as the fourth color light. The first optical adhesive layer 41 is designed to transmit the first color light, while the second optical adhesive layer 42 is intended for the fourth color light. For instance, if the first color light, second color light, and third color light correspond to red color, green color, and blue color, respectively, and the mixed fourth color light appears as yellow, then the first optical adhesive layer 41 is a red optical adhesive layer, and the second optical adhesive layer 42 is a yellow optical adhesive layer. This arrangement of the first and second optical adhesive layers enhances the color performance of the cholesteric liquid crystal display device 2. Furthermore, the first optical adhesive layer 41 and the second optical adhesive layer 42 also serve to strengthen the connection between adjacent transparent substrate.

In certain embodiments, each of the first cholesteric liquid crystal modules comprises the first cholesteric liquid crystal module 21, the second cholesteric liquid crystal module 22, and the third cholesteric liquid crystal module 23, consists of three layers stacked sequentially from bottom to top: a lower electrode layer 201, a cholesteric liquid crystal layer 202, and an upper electrode layer 203. The lower electrode layer 201 and the upper electrode layer 203 serve the purpose of applying voltage to the cholesteric liquid crystal layer 202, allowing for the adjustment of the molecular arrangement of the cholesteric liquid crystal layer 202. This adjustment, in turn, regulates the ratio of transmitted and reflected light. The transmitted light is harnessed to supply the solar module 30 with energy, while the reflected light is utilized to display image information.

In some embodiments, each of the first cholesteric liquid crystal module 21, the second cholesteric liquid crystal module 22, and the third cholesteric liquid crystal module 23 further comprises a reinforcement layer 204, and the reinforcement layer 204 is disposed between the lower electrode layer 201 and the upper electrode layer 203 to improve the overall structural stability.

In some embodiments, the driving scheme of the cholesteric liquid crystal display device 1 may be a passive matrix mode or an active matrix mode.

The present invention also provides a method for making a solar module 30 on the first transparent substrate 11. The method comprises the following steps: a transparent conductive material is used to implement a transparent electrode layer on the first transparent substrate 11; a hole transport layer 32 is formed on the transparent electrode layer; a perovskite light absorbing layer 33 is formed on the hole transport layer 32; an electron transport layer 34 is formed on the perovskite light absorption layer 33; and then an electron transport layer 34 is formed on the electron transport layer; a transparent electrode layer is formed on the transparent electrode layer 34; and an insulating layer 36 is formed on the transparent electrode layer. Subsequently, the driving circuit required for the first transparent substrate 11 of the cholesteric liquid crystal display device 1 is fabricated on the insulating layer 36; the driving circuit required for the cholesteric liquid crystal display device 1 is first fabricated on the second transparent substrate 12.

Therefore, with the cholesteric liquid crystal display device 1 integrated with the solar module 30 provided by the present invention, the light-transmitting characteristics of the cholesteric liquid crystal display device 1 are combined with the coating process characteristics. This integration allows the cholesteric liquid crystal display device 1 not only to display information but also to capture light energy and convert it into electrical energy for practical use, ultimately achieving the goals of environmental conservation and energy efficiency.

The descriptions illustrated above set forth simply the preferred embodiments of the present invention; however, the characteristics of the present invention are by no means restricted thereto. All changes, alterations, or modifications conveniently considered by those skilled in the art are deemed to be encompassed within the scope of the present invention set forth by the following claims.

What is claimed is:

1. A cholesteric liquid crystal display device integrated with solar modules, comprising:
a first transparent substrate;
a second transparent substrate;
a first cholesteric liquid crystal display module, disposed between the first transparent substrate and the second transparent substrate; and
a solar module, disposed between the first transparent substrate and the first cholesteric liquid crystal module;
wherein the cholesteric liquid crystal display device integrated with solar modules comprises the first transparent substrate, the solar module, the first cholesteric liquid crystal module, and the second transparent substrate, sequentially stacked from bottom to top.

2. The cholesteric liquid crystal display device integrated with solar modules according to claim 1, wherein the solar module comprises a first transparent electrode layer, a hole transport layer, a perovskite light absorption layer, an electron transport layer, a second transparent electrode layer, and an insulating layer sequentially stacked on the first transparent substrate.

3. The cholesteric liquid crystal display device integrated with solar modules according to claim 1, wherein the solar module is a perovskite solar photovoltaic device.

4. The cholesteric liquid crystal display device integrated with solar modules according to claim 1, wherein the display device further comprises a third transparent substrate, a second cholesteric liquid crystal module, a fourth transparent substrate, a fifth transparent substrate, a third cholesteric liquid crystal module, and a sixth transparent substrate, sequentially stacked on the second transparent substrate.

5. The cholesteric liquid crystal display device integrated with solar modules according to claim 4, wherein the display device further comprises a first optical adhesive layer and a second optical adhesive layer, and the first optical adhesive layer is positioned between the second transparent substrate and the third transparent substrate, while the second optical adhesive layer is provided between the fourth transparent substrate and the fifth transparent substrate.

6. The cholesteric liquid crystal display device integrated with solar modules according to claim 5, wherein the first cholesteric liquid crystal module generates the first color light, the second cholesteric liquid crystal module produces the second color light, the third cholesteric liquid crystal module is responsible for the third color light, wherein the first, second, and third color lights are distinct, and when the first color light and the second color light are mixed, the resulting color light is defined as the fourth color light, and the first optical adhesive layer is used to transmit the first color light, while the second optical adhesive layer is used to transmit the fourth color light.

7. The cholesteric liquid crystal display device integrated with solar modules according to claim 4, wherein each of the first cholesteric liquid crystal module, the second cholesteric liquid crystal module, and the third cholesteric liquid crystal module comprises a lower electrode layer, a cholesteric liquid crystal layer, and a upper electrode layer stacked in sequence.

8. The cholesteric liquid crystal display device integrated with solar modules according to claim 7, wherein each of the first cholesteric liquid crystal module, the second cholesteric liquid crystal module and the third cholesteric liquid crystal module further comprises a reinforcement layer, and the reinforcement layer is configured between the lower electrode layer and the upper electrode layer.

9. The cholesteric liquid crystal display device integrated with solar modules according to claim 1, wherein the driving scheme of the cholesteric liquid crystal display device is a passive matrix mode or an active matrix mode.

10. The cholesteric liquid crystal display device integrated with solar modules according to claim 1, wherein the display device further comprises a black absorption layer disposed on a side of the first transparent substrate away from the solar module.
